(19) United States
(12) Patent Application Publication
(10) Pub. No.: US 2026/0147022 A1
(43) Pub. Date: May 28, 2026

(54) Measuring an Electrical Current Using Two Optical Current Transformers

(71) Applicant: HSP Hochspannungsgeräte GmbH, Troisdorf (DE)

(72) Inventor: Stefan Schuberth, Lichtenfels-Schney (DE)

(21) Appl. No.: 19/121,753

(22) PCT Filed: Oct. 2, 2023
(86) PCT No.: PCT/EP2023/077232

§ 371 Date: Apr. 16, 2025

(30) Foreign Application Priority Data
Oct. 18, 2022 (DE) 10 2022 210 973.2

(51) Int. Cl. G01R 15/22; G01R 19/00

(52) U.S. Cl. CPC G01R 15/22; G01R 19/0092

(57) ABSTRACT

The invention relates to a method for measuring an electrical current (I). In the method, measurement signals (A) dependent on the current (I) are detected multiple times by each of at least two optical current transformers (5, 7), wherein the current transformers (5, 7) have differing unambiguous ranges (E1 to E4) in which the measurement signal (A) detected by the relevant current transformer (5, 7) monotonously increases or decreases as the current (I) increases. A sign value is continually determined for each current transformer (5, 7), the sign value indicating the sign of the first derivative of the measurement signal (A) detected by the current transformer (5, 7) with respect to the current (I). A modified unambiguous range (E1 to E4) of the current transformer (5, 7) is associated with the measurement signals (A) from a current transformer (5, 7) if the sign value determined for this current transformer (5, 7) changes and the sign value determined for at least one other current transformer (5, 7) does not change. The amperage of the electrical current (I) is determined from the measurement signals (A) from at least one current transformer (5, 7).

The invention relates to measuring an electrical current using an optical current transformer.

Here, an optical current transformer is understood to mean an optical measuring device for measuring an electrical current in an electric conductor which is based on the magnetooptical Faraday effect. This effect is understood as the rotation of the polarisation direction of a linearly polarised electromagnetic wave in a medium due to a magnetic field in parallel with the propagation direction of the wave. In this case, the rotation of the polarisation direction is proportional to the magnetic flux density of the magnetic field.

In the case of an optical current transformer, linearly polarised light is sent through an optical fibre, arranged in the vicinity of the optical current transformer, which exhibits the Faraday effect. The magnetic field generated by the current in the electric conductor causes a rotation of the polarisation direction of the light. Since the magnetic flux density of the magnetic field depends on the amperage of the current, the amperage can be measured in that the rotation of the polarisation direction of the light is detected. In order to detect the rotation of the polarisation direction, the light emitted by the optical fibre is for example guided through a polariser and a light intensity of the light transmitted by the polariser is detected.

The measuring principle of an optical current transformer implies that the measurement signals of the optical current transformer do not provide any clear function of the amperage of the current to be measured, since different amperages lead to the same measurement signal. The values of the amperages form successive unambiguous ranges, in which the measurement signal of the optical current transformer monotonously increases or decreases in each case as the amperage increases. In this case, each unambiguous range in which the measurement signal of the optical current transformer monotonously increases with the increasing amperage from a minimum to a maximum is followed by an unambiguous range in which the measurement signal of the optical current transformer monotonously decreases with increasing amperage from the maximum to the minimum, and each unambiguous range in which the measurement signal of the optical current transformer monotonously decreases with increasing amperage from the maximum to the minimum is followed by an unambiguous range in which the measurement signal of the optical current transformer increases monotonously with increasing amperage from the minimum to the maximum.

The object of the invention is that of specifying an improved method and an improved measuring device for measuring an electrical current using an optical current transformer.

In the method according to the invention for measuring an electrical current, measurement signals dependent on the current are detected repeatedly in each case by means of at least two optical current transformers, wherein the optical current transformers have differing unambiguous ranges in which the measurement signal detected by the respective optical current transformer monotonously increases or decreases as the current increases. A sign value is continually determined for each optical current transformer, the sign value indicating the sign of the first derivative of the measurement signal, with respect to the current I, detected by the optical current transformer. A modified unambiguous range of the optical current transformer is associated with the measurement signals from an optical current transformer if the sign value determined for this optical current transformer changes and the sign value determined for at least one other optical current transformer does not change. The amperage of the electrical current is determined from the measurement signals from at least one optical current transformer.

The method according to the invention thus provides using a plurality of optical current transformers for measuring an electrical current, wherein the optical current transformers have differing unambiguous ranges in which the measurement signal detected by the respective optical current transformer monotonously increases or decreases as the current increases. The use of a plurality of optical current transformers having differing unambiguous ranges makes it possible to solve the problem of the ambiguity of the measurement signal of an optical current transformer as a function of the current to be measured, in that at least one further optical current transformer is used to determine the respective unambiguous range of said optical current transformer. In order to reliably ascertain the change between different unambiguous ranges, the invention provides that a sign value is continually determined for each of said optical current transformers, which sign value indicates the sign of the first derivative of the measurement signal detected by the optical current transformer. The change in the sign value of an optical current transformer when there is no change in the sign value of another optical current transformer reliably signals that the unambiguous range of the optical current transformer has changed.

In one embodiment of the method according to the invention, no optical current transformer has an unambiguous range that is a multiple of an unambiguous range of another optical current transformer. This embodiment of the invention takes into account the fact that an unambiguous range of one optical current transformer that is a multiple of an unambiguous range of another optical current transformer results in their being amperages of the electrical current to be measured in which the unambiguous ranges of the two optical current transformers change simultaneously, such that it is not possible, in the case of these amperages, to use one optical current transformer for controlling the other optical current transformer.

In a further embodiment of the method according to the invention, the measurement signals of each optical current transformer are digitised measurement signals which assume values from a value range assigned to the optical current transformer, and the entire value range is used for each unambiguous range of the optical current transformer. This embodiment of the invention makes use of the fact that the invention allows for an unambiguous determination of the respective unambiguous range of an optical current transformer. Therefore, for each unambiguous range of an optical current transformer the entire value range assigned to said optical current transformer can be used for recording digital measurement signals. In other words, different unambiguous ranges do not need to be associated with a separate subset of the value range in each case. As a result, the memory requirement for the digital measurement signals is advantageously significantly reduced at the same resolution of the measurement signals, or the resolution of the measurement signals is advantageously significantly increased at the same memory space.

In a further embodiment of the method according to the invention, each optical current transformer comprises an optical waveguide, and the optical waveguides of at least two optical current transformers are produced from differing materials, in particular from materials having differing Verdet constants.

In a further embodiment of the method according to the invention, electromagnetic radiation of a wavelength specific for the optical current transformer is conducted through each optical current transformer, and the wavelengths of at least two optical current transformers differ from one another.

The two above-mentioned embodiments of the invention allow for the configuration of optical current transformers having differing unambiguous ranges by using optical waveguides of different materials and/or electromagnetic radiation of different wavelengths.

A measuring device according to the invention for measuring an electrical current comprises:
at least two optical current transformers which are each configured to repeatedly detect measurement signals dependent on the current, wherein the optical current transformers have differing unambiguous ranges in which the measurement signal detected by the respective optical current transformer monotonously increases or decreases as the current increases, and
an evaluation unit, which is configured
to continually determine a sign value for each optical current transformer, which sign value indicates the sign of a first derivative of the measurement signal, with respect to the current, detected by the optical current transformer,
to assign a changed unambiguous range of the optical current transformer to the measurement signals of an optical current transformer if the sign value determined for this optical current transformer changes and the sign value determined for the at least one other optical current transformer does not change, and
to determine the amperage of the electrical current from the measurement signals of at least one optical current transformer.

A measuring device according to the invention for measuring an electrical current makes it possible to carry out the method according to the invention. The advantages of such a measuring device therefore correspond to the above-mentioned advantages of the method according to the invention. Similar applies for the following embodiments of a measuring device according to the invention, which correspond to the above-mentioned embodiments of the method according to the invention.

In one embodiment of the measuring device according to the invention, no optical current transformer has an unambiguous range that is a multiple of an unambiguous range of another optical current transformer.

In a further embodiment of the measuring device according to the invention, the measuring signals of each optical current transformer are digitised measurement signals which assume values from a value range assigned to the optical current transformer, and the evaluation unit is configured to use the entire value range for each unambiguous range of the optical current transformer.

In a further embodiment of the measuring device according to the invention, each optical current transformer comprises an optical waveguide, and the optical waveguides of at least two optical current transformers are produced from differing materials, in particular from materials having differing Verdet constants.

In a further embodiment of the measuring device according to the invention, each optical current transformer is configured for guiding electromagnetic radiation of a wavelength specific for the optical current transformer, and the wavelengths of at least two optical current transformers differ from one another.

The above-described properties, features and advantages of this invention, as well as the way in which these are achieved, will become clearer and easier to understand in connection with the following description of embodiments which are explained in more detail with reference to the drawings, in which:

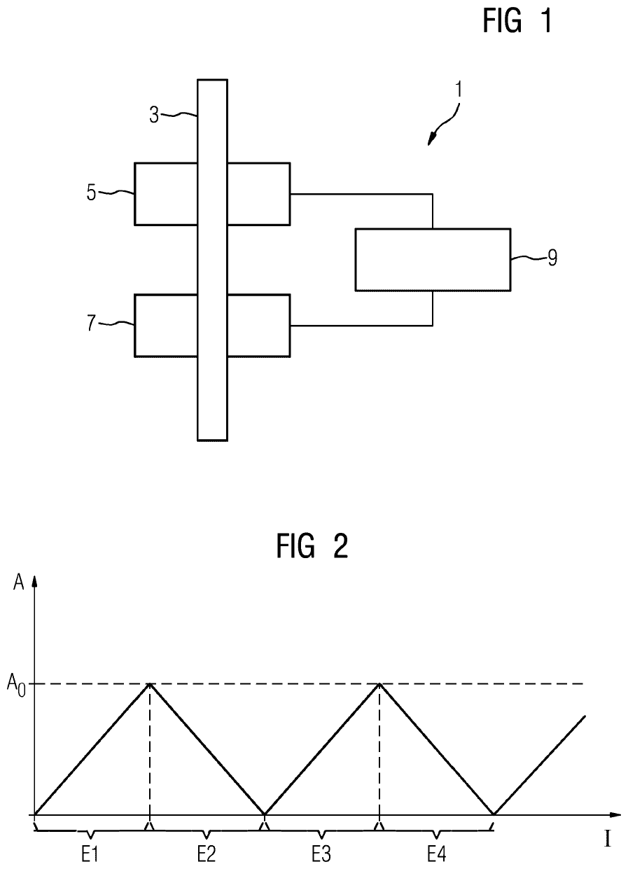

FIG. 1 is a block diagram of an embodiment of a measuring device for measuring an electrical current,

FIG. 2 shows measurement signals of an optical current transformer depending on an electrical current,

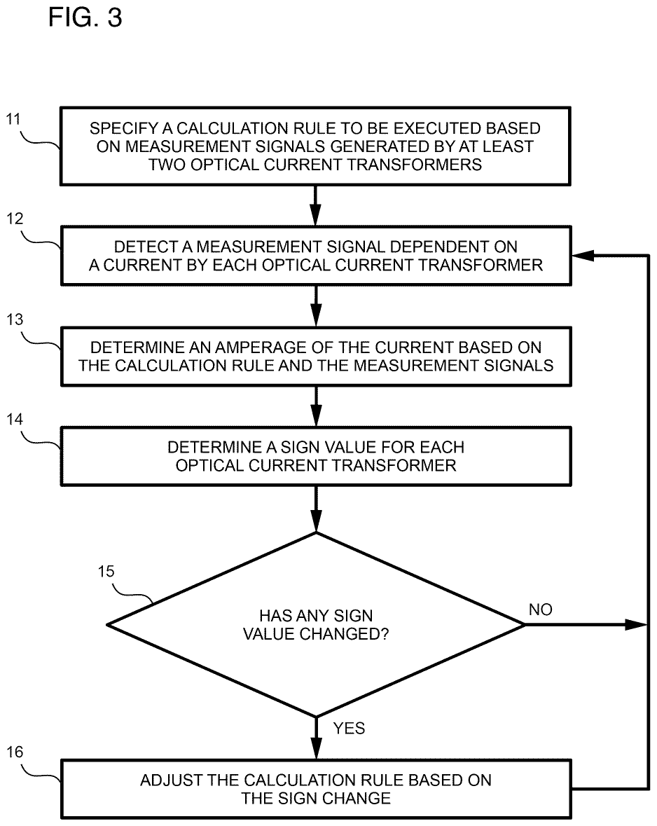

FIG. 3 is a flow diagram of an embodiment of a method for measuring an electrical current.

FIG. 1 is a block diagram of an embodiment of a measuring device 1 for measuring an electrical current I flowing in an electric conductor 3. The measuring device 1 comprises two optical current transformers 5, 7 and an evaluation unit 9.

Each optical current transformer 5, 7 is configured to repeatedly detect measurement signals A that are dependent on the current I.

FIG. 2 schematically shows measurement signals A detected by an optical current transformer 5, 7 depending on the electrical current I. Each optical current transformer 5, 7 has unambiguous ranges E1 to E4, in which the measurement signal A detected by the optical current transformer 5, 7 monotonously increases or decreases as the current I increases. FIG. 2 shows, by way of example, two unambiguous ranges E1, E3 in which the measurement signal A monotonously increases as the current I increases, from the value A=0 to a maximum value A=A₀, and two unambiguous ranges E2, E4 in which the measurement signal A monotonously decreases as the current I increases, from the maximum value A=A₀ to the value A=0. Each unambiguous range E1, E3 in which the measurement signal A monotonously increases as the current I increases is adjoined by an unambiguous range E2, E4 in which the measurement signal A monotonously decreases as the current I increases. Each unambiguous range E2, E4 in which the measurement signal A monotonously decreases as the current I increases is adjoined by an unambiguous range E1, E3 in which the measurement signal A monotonously decreases as the current I increases.

The two optical current transformers 5, 7 of the measuring device 1 have differing unambiguous ranges E1 to E4, wherein no optical current transformer 5, 7 has an unambiguous range E1 to E4 that is a multiple of an unambiguous range E1 to E4 of the other optical current transformer 5, 7. For example, the optical current transformers 5, 7 each comprise an optical waveguide, and the optical waveguides of the two optical current transformers 5, 7 are produced from differing materials, in particular from materials having differing Verdet constants. Alternatively or in addition, electromagnetic radiation of a wavelength specific for the optical current transformer 5, 7 is guided through each optical current transformer 5, 7, wherein the wavelengths of the two optical current transformers 5, 7 differ from one another.

The evaluation unit 9 is configured to continually determine a sign value for each optical current transformer 5, 7, which sign value indicates the sign of the first derivative of the measurement signal A, with respect to the current I, detected by the optical current transformer 5, 7. Furthermore, the evaluation unit 9 is configured to assign a modified unambiguous range E1 to E4 of the optical current transformer 5, 7 to the measurement signals A of each optical current transformer 5, 7 if the sign value determined for this optical current transformer 5, 7 changes and the sign value determined for the other optical current transformer 5, 7 does not change. Furthermore, the evaluation unit 9 is configured for determining the amperage of the electrical current I from the measurement signals A of at least one optical current transformer 5, 7. For example, the evaluation unit 9 is configured to determine the amperage of the electrical current I from the measurement signals A of the optical current transformer 5, 7 which has the greater measurement sensitivity of the two optical current transformers 5, 7. Alternatively, the evaluation unit 9 is for example configured to determine the amperage of the electrical current I from an average or weighted average of the measurement signals A of the two optical current transformers 5, 7.

FIG. 3 shows a flow diagram of an embodiment of the method according to the invention for measuring an electrical current I. The method is carried out using a measuring device 1 described with reference to FIGS. 1 and 2.

In a first method step 11, a calculation rule to be executed by the evaluation unit 9 is specified, by means of which the amperage of an electrical current I flowing in the electric conductor 3 is determined from the measurement signals A detected by the optical current transformers 5, 7. For example, the calculation rule provides for determining the amperage of the electrical current I from the measurement signals A of the optical current transformer 5, 7 which has the greater measurement sensitivity of the two optical current transformers 5, 7. In this case, the calculation rule depends on the unambiguous range E1 to E4 of the optical current transformer 5, 7 that corresponds to the amperage. If the measurement signals A of the optical current transformer 5, 7, for example as in the example shown in FIG. 2, in the unambiguous ranges E1 to E4 each depend linearly on the current I, then the calculation rule in the unambiguous range E1 is of the form I=f·A having a proportionality constant f, in the unambiguous range E2 the calculation rule is in the form of I=f·(2A₀−A), etc.

Alternatively, the calculation rule provides, for example, for determining the amperage of the electrical current I from an average or weighted average of the measurement signals A of the two optical current transformers 5, 7. In this case, the calculation rule depends, correspondingly, on the unambiguous ranges E1 to E4 of the optical current transformers 5, 7 that correspond to the amperages.

After the first method step 11, a second method step 12 is carried out.

In the second method step 12 a measurement signal A dependent on the current I is detected by each optical current transformer 5, 7. The measurement signal A of each optical current transformer 5, 7 is a measurement signal digitised by an analogue-to-digital converter, which assumes a value from a value range determining the resolution of the analogue-to-digital converter. In this case, different analogue-to-digital converters, in particular analogue-to-digital converters having value ranges different from one another, can be used for the two optical current transformers 5, 7.

For example, for a first optical current transformer 5, 7 an 8-bit analogue-to-digital converter is used, the value range of which thus has 256 values, and for the second optical current transformer 5, 7 a 16-bit analogue-to-digital converter is used, the value range of which thus has 65536 values. In this example, preferably the measurement signals A of the second optical current transformer 5, 7 are used in order to determine the amperage of the current I, and the first optical current transformer 5, 7 is used in order to check the plausibility of the measurement signals A of the second optical current transformer 5, 7.

In this case, the entire value range of the analogue-to-digital converter associated with one optical current transformer 5, 7 is used for all the measurement signals A in the respective unambiguous range E1 to E4 of the optical current transformer 5, 7.

After the second method step 12, a third method stop 13 is carried out.

In the third method step 13, the evaluation unit 9 determines the amperage of the current I according to the current calculation rule in each case, from the measurement signals A detected in the second method step 12.

After the third method step 13, a fourth method step 14 is carried out.

In the fourth method step 14, the evaluation unit 9 determines a sign value for each optical current transformer 5, 7, which sign value indicates the first derivative of the measurement signal A, with respect to the current I, detected by the optical current transformer 5, 7. For this purpose, the evaluation unit 9 evaluates temporally successive measurement signals A of each optical current transformer 5, 7.

After the fourth method step 14, a fifth method step 15 is carried out.

In the fifth method step 15, the evaluation unit 9 checks whether the sign value determined in the fourth method step 14 for an optical current transformer 5, 7, the measurement signals A of which are used for determining the amperage of the current I, has changed relative to the previous sign value for said optical current transformer 5, 7. If this is not the case, following the method step 15 the second method step 12 is carried out again. Otherwise, a sixth method step 16 is carried out.

In the sixth method step 16, the calculation rule, by which the amperage of the electrical current I flowing in the electric conductor 13 is determined from the measurement signals A detected by the optical current transformers 5, 7, is changed. In this case, the optical current transformer 5, 7 for which a changed sign value was identified in the fifth method step 15 is assigned an unambiguous range E1 to E4 which adjoins the unambiguous range E1 to E4 previously assigned to said optical current transformer 5, 7 and which corresponds to the current amperage in each case, and the calculation rule is adjusted to the changed unambiguous range E1 to E4 of the optical current transformer 5, 7.

After the sixth method step 16, the second method step 12 is carried out again.

Although the invention has been illustrated and described in more detail on the basis of preferred embodiments, the invention is not limited by the disclosed examples and a person skilled in the art can derive other variations therefrom, without departing from the scope of protection of the invention.

1. A method comprising:
repeatedly detecting one or more measurement signals dependent on an electrical current using at least two optical current transformers, wherein;
the optical current transformers have differing unambiguous ranges in which the measurement signals detected by each respective optical current transformer monotonously increase or decrease as the electrical current increases;
continually determining a sign value for each optical current transformer, the sign value indicating a sign of a first derivative of an associated measurement signal of the measurement signals with respect to the electrical current as detected by the respective optical current transformer;
associating a modified unambiguous range of each optical current transformer with a subset of measurement signals of the measurement signals associated with the corresponding optical current transformer if the sign value determined for this optical current transformer changes and the sign value determined for at least one other optical current transformer does not change; and
determining an amperage of the electrical current from the measurement signals of at least one optical current transformer.

2. The method according to claim 1, wherein no optical current transformer has an unambiguous range that is a multiple of an unambiguous range of another optical current transformer.

3. The method according to claim wherein the measurement signals of each optical current transformer are digitised measurement signals which can assume values from a value range assigned to the optical current transformer, and wherein the entire value range is used for the unambiguous range of the each optical current transformer.

4. The method according to claim 1, wherein each optical current transformer includes an optical waveguide and the optical waveguides of at least two optical current transformers are produced from different materials.

5. The method according to claim 4, wherein the optical waveguides of at least two optical current transformers are produced from materials having different Verdot constants.

6. The method according to claim 1, wherein electromagnetic radiation of a wavelength specific for an optical current transformer of the optical current transformers is conducted through each optical current transformer, and the wavelengths of at least two optical current transformers differ from one another.

7. A measuring device for measuring an electrical current, the measuring device comprising:
at least two optical current transformers which are each configured to repeatedly detect one or more measurement signals dependent on the electrical current, wherein the optical current transformers have differing unambiguous ranges in which the measurement signals detected by the respective optical current transformer monotonously increases or decrease as the electrical current increases; and
an evaluation unit, which is configured to:
continually determine a sign value for each optical current transformer, the sign value indicating a sign of a first derivative of an associated measurement signal of the measurement signals with respect to the electrical current as detected by the respective optical current transformer;
assign a modified unambiguous range of each optical current transformer to a subset of measurement signals of the measurement signals associated with the corresponding optical current transformer if the sign value determined for this optical current transformer changes and the sign value determined for at least one other optical current transformer does not change; and
determine an amperage of the electrical current from the measurement signals of at least one optical current transformer.

8. The measuring device according to claim 7, wherein no optical current transformer has an unambiguous range that is a multiple of an unambiguous range of another optical current transformer.

9. The measuring device according to claim 7, wherein the measurement signals of each optical current transformer are digitised measurement signals which assume values from a value range assigned to the respective optical current transformer, and the evaluation unit is configured to use the entire value range for the unambiguous range of each optical current transformer.

10. The measuring device according to claim 7, wherein each optical current transformer comprises an optical waveguide and the optical waveguides of at least two optical current transformers are produced from different materials.

11. The measuring device according to claim 10, wherein the optical waveguides of at least two optical current transformers are produced from materials having different Verdet constants.

12. The measuring device according to claim 7, wherein each optical current transformer is configured to conduct electromagnetic radiation of a wavelength specific for the optical current transformer, and the wavelengths of at least two optical current transformers differ from one another.
